(19) United States
(12) Patent Application Publication
(10) Pub. No.: US 2026/0066593 A1
(43) Pub. Date: Mar. 5, 2026

(54) MIXING CONSOLE SWITCHING DEVICE

(71) Applicants: Mark A. Parker, Allen, OK (US); Steven C. Parker, Hendersonville, TN (US)

(72) Inventors: Mark A. Parker, Allen, OK (US); Steven C. Parker, Hendersonville, TN (US)

(21) Appl. No.: 18/821,668

(22) Filed: Aug. 30, 2024

(51) Int. Cl. H01R 13/71; H05K 5/00; H05K 7/14

(52) U.S. Cl. CPC H01R 13/71; H05K 5/0017; H05K 7/14

(57) ABSTRACT

A mix switcher with a simplified user interface and user operation having first and second audio channel input connectors (or more) and an audio channel output connector, with a portion of a user control panel having user-operable switches including a channel selection switch to one and only one input audio signal to the audio channel output and a mute switch to short two audio signal conductors of the audio channel output connector to each other during selection changes from one input to the other input.

### BACKGROUND OF THE INVENTION

Mixing consoles are well-known components in live and recorded music and audio production. Older mixing consoles comprised analog “faders” (e.g., potentiometers) with tube-based or electronic amplifiers to allow the operator to select how much signal from multiple signal inputs would be added into the final output signal, which is typically routed to a power amplifier which then drives one or more speakers. Modern mixing consoles replace the analog faders with digitally-controlled faders, and include digital signal processing to mute specific inputs, filter and condition certain signals, and remove unwanted noise and feedback automatically.

During live performances, there may be a need to produce two or more bands, DJ's, MC's, or other sources. In order to reduce the need for a mixer console for each of these sources, and to reduce the need for the operator to know how to operate two or more mixing consoles, there often is an objective to use just one final mixing console and to switch the cable inputs as the event progresses. In modern practice, each source (band, DJ, MC, narrator, commenter, etc.) has their own mixing console into which all of their microphone, guitar, keyboard, effects, etc., cables are plugged. Then, each performer can create a first mixed output for a left channel, a right channel, a subwoofer channel, and a fill channel outputs from their own mixing console. These outputs are run by cable to the “back of the house” where the room mixing console is located. There, the master mixing console operator determines how much of each signal is sent to the room amplifiers and to the room left-channel speakers, right-channel speakers, subwoofer speakers, and fill speakers. When the source of the production or show changes, the next source has their own mixer, so the room mixer operator must unplug all of the input cables from the first source or act, and plug in the input cables from the next act's own mixer.

For example, after an “opening” band at the “front of the house” (e.g., a stage in front of a section of audience seating) completes their performance, all of the cables coming from the outputs of the opening band's mixer must be unplugged from the room mixer's inputs, and all of the cables coming from the outputs of the “headliner” band's mixer must be plugged into the room mixer's inputs.

### SUMMARY OF THE INVENTION

A mix switcher with a simplified user interface and user operation is disclosed having first and second (or more) audio channel input connectors and an audio channel output connector, with a portion of a user control panel having user-operable switches including a channel selection switch to one and only one input audio signal to the audio channel output and a mute switch to short two audio signal conductors of the audio channel output connector to each other during selection changes from one input to the other input.

### BRIEF DESCRIPTION OF DRAWINGS

The following drawings, when taken in consideration with the disclosure, illustrate at least one embodiment of the present invention:

FIG. 1 illustrates a wiring diagram for a single channel switching unit according to at least one embodiment of the present invention.

FIG. 2 illustrates a two-source embodiment for Left, Right, Sub and Fill (L, R, S, F) channels using four of the switching units of FIG. 1 according to at least one embodiment of the present invention.

FIG. 3 shows a front panel arrangement according to at least one embodiment of the present invention.

FIG. 4 depicts a manner of using the example embodiment of FIGS. 2 and 3 according to at least one embodiment of the present invention.

FIG. 5 illustrates a well-known arrangement of components for audio production of a two-band live performance.

FIG. 6 illustrates an improved arrangement of components for audio production of a two-band live performance according to at least one embodiment of the present invention.

FIG. 7 illustrates another improved arrangement of components for audio production of a two-band live performance according to at least one embodiment of the present invention.

### DETAILED DESCRIPTION OF THE INVENTION

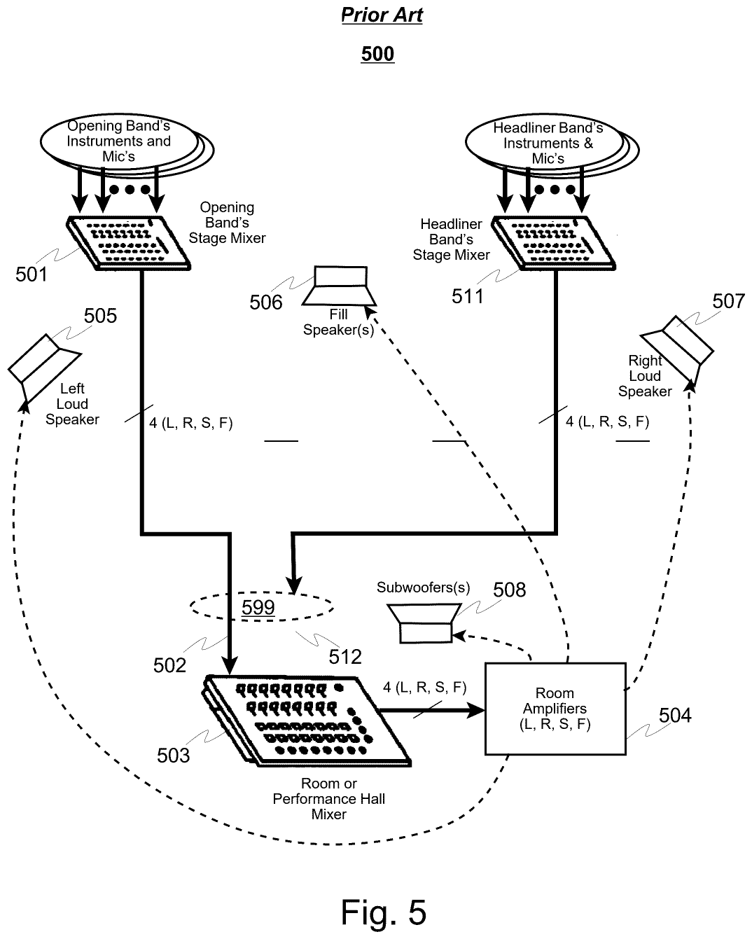

The present inventors have recognized and solved several long-standing, unmet needs in the arts of audio production, including recording studios, but especially for live audio production including a plurality bands, orators, DJ's, MC's, narrators, commenters, and the like. For example, consider the performance arrangement 500 of components shown in FIG. 5. In this arrangement, two bands will play, one after the other, at the “front of the house”, such as on a stage. The first or opening band has a stage mixer 501 which is uses to mix all of its instruments, microphones, effects, playback devices, etc., into a set of output cables 502, including, for example, four XLR cables, one each for Left, Right, Sub, and Fill signals. This first set of cables 502 from the opening band's stage mixer 501 is plugged into the inputs of the room or performance hall's mixer 503, where an operator controls the volumes of each speaker in the room. The room or performance hall mixer's outputs are cabled into one or more power amplifiers 504, from which the signals are cabled to each loud speaker 505, 506, 507 and 508 in the room or performance hall.

When the first or opening band has completed its performance, the operator of the room mixer 503 then manually (by hand) unplugs 599 the first set of cables 502 from the first stage mixer 501, and then plugs a second set of cables 512 from the second or headliner band's stage mixer 511 into the inputs of the room or performance hall mixer 503. Now, the mixing and amplifiers are ready to be used by the second ban during its performance.

This arrangement can be modified for a number of other configurations for multiple performers, bands, MC's, DJ's, presenters, commenters, narrators, etc., as is well understood in the art.

Also known in the art is that there is often a voltage or ground offset between each of the sets of cables 502, 512 to be swapped into and out of the room mixer. So, if the operator of the room or performance hall mixer 503 forgets to press “mute” on all four channels of the room or performance hall mixer 503 or forgets to fade all channels to zero, a large impulse can be sent during the cable swapping 599 to the amplifiers, which then is sent to the speakers. This results in a very unprofessional and startling loud “pop” on the speakers, which can damage the speakers as well.

Despite this being a well known problem, it happens often, even with seasoned professional mixing console operators. Pressures of time, confusion, distractions, etc., all lead to this situation, and nearly everyone who has ever attended a live, amplified performance of some sort has heard it many times.

To address this problem, several very sophisticated “mix switches” have been brought to market. These devices receive all of the sets of cables into their inputs simultaneously. Most, if not all, of them digitize the analog signals received on the cables through the XLR connectors, and then deal with muting in the digital domain, while also offering many pre-filtering, pre-conditioning, and other special effects. They are so sophisticated that some operators consider them to be a mixer of their own. Offering so much functionality, their user interfaces often include many different displays, option buttons, up/down/left/right keys for navigating menus, recalling pre-determined setups, etc. While being “feature rich”, they are also difficult to use (due to all of the options, screens, menus, etc.), and quite expensive.

The present inventors have realized that these smart, digital mix switches are overkill both for the needed basic function of switching input cables to a room mixer, and overkill for the budgetary capacities of many live performance production companies. Additionally, even with the expensive and complicated digital mix switches are employed in a live audio performance production equipment arrangement, the operators are likely to make errors using it, leading to gaps (silent periods of time) in the performance, etc.

For these reasons, and unable to find simpler, easier-to-use and more affordable mixer console switchers, the present inventors, being live audio production engineers themselves, set about designing such a solution. The following paragraphs detail at least one embodiment of their invention, which can be readily adapted to a wide range of live performance situations for multiple, sequential performers, bands, presenters, DJ's, MC's, commenters and narrators.

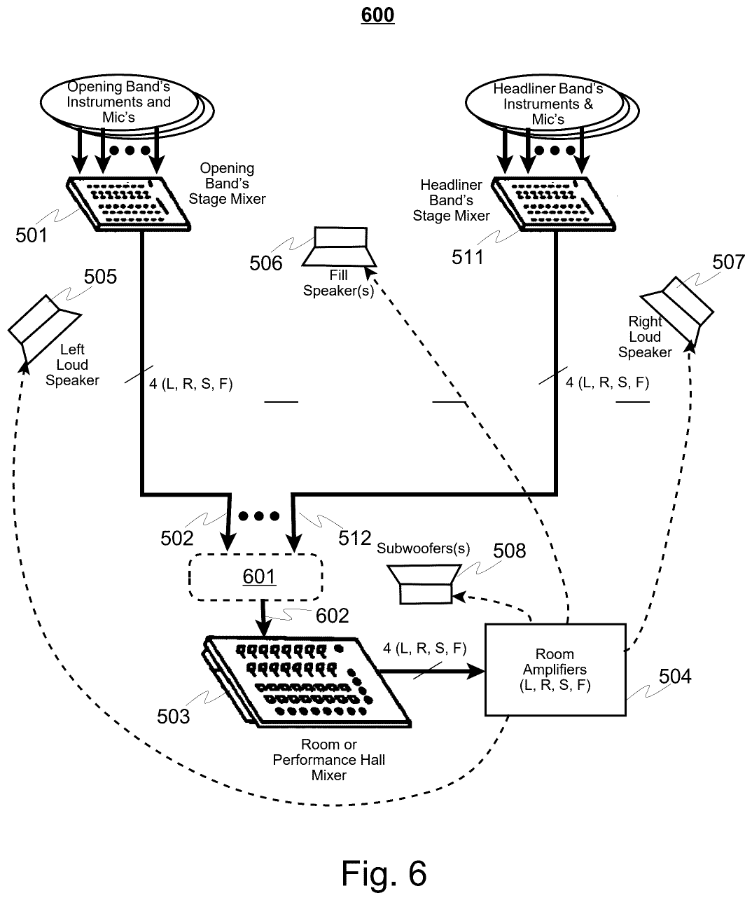

A First Example of Method of Using the Simplified Mix Switcher. Referring now to FIG. 6, a new simplified mix switcher 601 is shown 600 receiving two or more sets of cables 502, 512 from performer mixers. In at least one embodiment, the new mix switcher 601 has two sets of inputs (e.g., Left, Right, Subwoofer an Fill) 502, 512 and one set of outputs (1×L, R, S, F) 602, and the user interface is essentially a “toggle” switch, without any signal digitization, pre-amplifying, conditioning, filtering or other processing of the received signals. The operator simply chooses A or B as the current output to the room mixer 503 by toggling a switch. This basic embodiment preferably includes one or more analog (metallic) mute switches which the operator can easily see are either muted or unmuted, during the transition from A to B inputs. In this example embodiment, the signal path is wires (crimped, soldered, etc.), and the switches are analog, which will cause no clipping, distortion, filtering, etc., and introduce no influences on the signals that additional cabling wouldn't introduce.

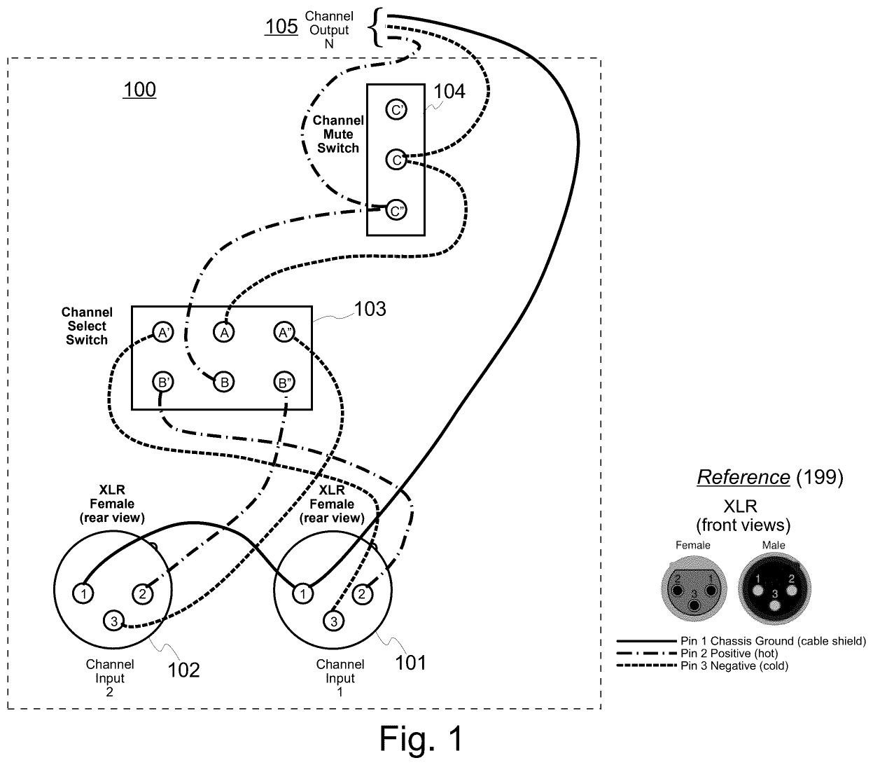

Example Simplified Mix Switcher Circuit Design. Turning now to FIG. 1, an example switch unit 100 according to the present invention is shown for selecting between a first cable input 101 and a second cable input 102, which we will refer to as “channels”. Each presenter, band, DJ, etc., would have their own channel. So, for the forgoing example of an opener band and a headliner band, the opener may be assigned the first channel and the headliner the second channel. For reference, the standard or conventional pin assignment 199 for XLR connectors is provided from frontal views of the female and male connectors. The routing of the signal for Pin 1 (chassis ground and/or cable shield) is illustrated in the switch unit 100 using a solid line. The routing of the signal for Pin 2 (positive or hot) is illustrated in the switch unit 100 using a dash-dot-dash line. The routing of the signal for Pin 3 (negative or cold) is illustrated in the switch unit 100 using a dashed line.

In the signal routing for the switch unit 100, please note that the pinout for the female XLR connectors is shown from the rear, such as an assembly technician would see it when panel-mount connectors are used and the connectors are mounted to a panel of metal for mounting in a typical audio equipment rack. Other embodiments may implement the switch unit within a desktop or table top case, as well.

In this example switch unit, a double-pole double-throw (DPDT) break-before-make toggle switch is used for the input channel selector 103 such that, when the toggle is moved into a position towards the right (viewed from the rear), pins 2 and 3 (positive and negative signals) of the Channel Input 1 XLR connector 101 are connected through the A′ and B′ terminals of the switch to the A and B terminals of the switch 103, respectively, and the A″ and B″ terminals are disconnected from the A and B terminals of the switch 103. When the toggle of the channel selector switch 103 is moved into a position towards the left (viewed from the rear), pins 2 and 3 (positive and negative signals) of the Channel Input 2 XLR connector 102 are connected through the A″ and B″ terminals of the switch to the A and B terminals of the switch 103, respectively, and the A′ and B′ terminals are disconnected from the A and B terminals of the switch 103. Pins 1 (chassis ground and cable shields) of Channel Input 1 XLR connector 101 and Channel Input 2 XLR connector 102 are permanently (unswitched) connected together, and connected to the chassis ground output wire in the channel output wires 105, which helps eliminate any voltage differences and/or ground loops between the sets of inputs from the different performer's stage mixers.

A simple-to-use mute function is provided by a single-pole double-throw (SPDT) toggle switch 104 in this example embodiment, although it is utilized as a single-pole single-throw (SPST) switch. In this example, the hot signal present on the B terminal of the channel selector switch 103 is temporarily connected to the negative signal present on the A terminal of the channel selector switch 103 when the switch 104 is in the “mute” position. By shorting the balanced signal wires to each other, the voltage difference is driven to zero, which will eliminate any pop or large impulse being sent through the mixing console to the amplifiers and speakers.

In this example switch unit embodiment, all signal interconnects can be accomplished by soldering or crimping wires, making it easy to debug, repair, and understand for a typical sound mixer operator as they are usually adept at repairing cables and connectors and have all the tools necessary to cut, strip and solder or crimp audio cable wires. Other embodiments may use printed circuit boards to implement the signal interconnects.

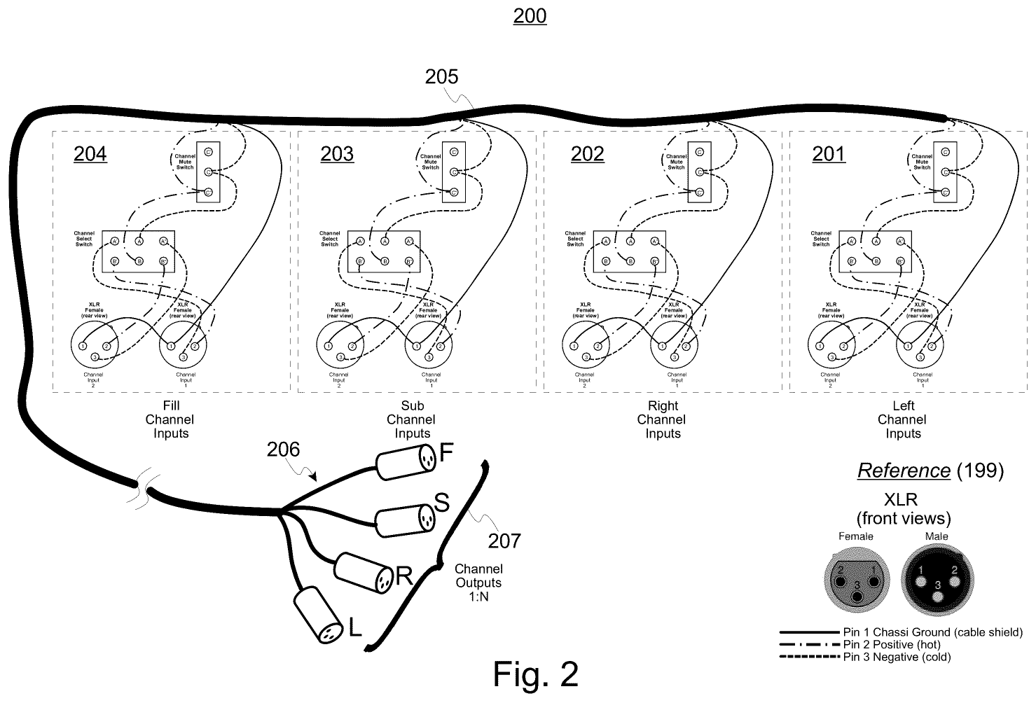

Referring now to FIG. 2, four switch units 201, 202, 203 and 204, are shown to yield a 4-signal (Left, Right, Sub, Fill) 2-channel mix switch 200, taken from a rear view of the panel of the embodiment. Each switch unit is wired according to the depiction and description of FIG. 1. The outputs of each switch unit are combined into a bundle of wires which are terminated with male XLR connectors 207, suitable for plugging into the amplifiers for each respective signal. In at least one embodiment, the combined output cable bundle 205 is 6-feet long with a 6-inch fan 206 at the end with the male XLR connectors.

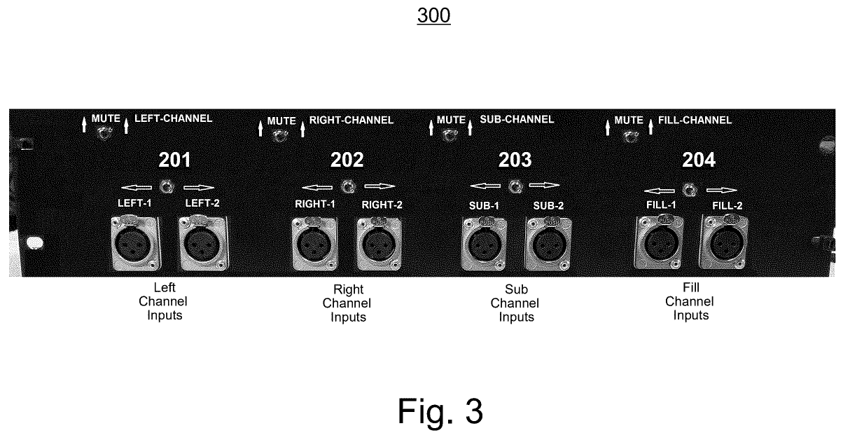

FIG. 3 provides a front view 300 of a panel according to FIGS. 1 and 2 which is mountable in a typical audio equipment rack. Because this is a front view instead of a rear view, all of the pins and switch units swap position horizontally, of course. So, the left channel inputs (A and B or 1 and 2) are on the leftmost switch unit 201, proceeding towards the right with the right channel inputs 202, sub channel inputs 203, and fill channel inputs 204. From this view, one can see the intuitive nature of the simplified user interface—the toggle of each channel selector switch literally points mechanically towards the selected channel input. Not only is this very easy to understand visually, without the need learn to navigate menus or push buttons and illuminate indicators (is lit selected or mute?), it is also intuitive to use in the dark when the operator's only feedback from the mix switch is tactile. Similarly, the mute switches for each channel are simple to learn to use—up is muted (hot and cold shorted together), and down is unmuted. Again, very quick to learn, easy to debug and repair, and can be operated and checked in the dark by feel.

Optimized and Minimized User Interface. The particular arrangement of connectors and switches shown 300 in FIG. 3 is optimized and minimized as described in the foregoing paragraphs, but also has additional advantages to be noticed. By placing the XLR connectors at the bottom of the panel and the switches above the XLR connectors, when cables are plugged into the unit, they will drape downward, away from the switches. In this arrangement, finger access to the switches will not be interfered with by the cables, nor will visual inspection of the switch positions and labels be blocked by the cables.

Other Simplified Mix Switcher Circuit Embodiments. An advantage of the all-metallic (e.g., hard switches, wires, etc.) embodiment of the foregoing paragraphs is that it:
(a) does not introduce any affects on the signals other than what is introduced by cabling,
(b) can be understood and used easily with little to no learning curve, and
(c) can be repaired using skills and tools commonly had by mixing console operators.

Still further, the all analog, all metallic switching embodiment needs no power to operate—it is entirely passive in its function, so to speak. So, there is no the mix switcher can introduce any power supply-related noise into the audio, such as 50 Hz or 60 Hz “hum”. However, those skilled in the relevant arts will readily recognize that other embodiments are available within the scope of the present invention.

For example, instead of toggle switches, some embodiments may use rotary switches or even N-pole N-throw switches so that the operator has to perform fewer switch operations to accomplish an input changeover. In the foregoing example embodiments, a single 8-pole 8-throw analog switch could select between inputs A or inputs B (L, R, S, F) in a single move. Such switches can be expensive and more difficult to get, so making repairs could be complicated, but ease of operation improved.

Still further, if three-position switches are used instead of two position, and if make-before-break switches are used, the muting function can be implemented on the third (middle) position of the switch, thereby eliminating the need for separate mute switches and separate mute operational steps when changing over from one set of inputs to another set of inputs.

In another example, the physical, metallic (analog) switches may be replaced with electronic switches, and potentially with unity-gain amplifiers. This could allow for single-button switch from one set of inputs to the another set of inputs, but would add the requirement of a power supply.

Those ordinarily skilled in the arts will also recognize that XLR connectors may be substituted with other common types of audio connectors, such as RCA, ¼″ plugs, and the like, within the spirit and scope of the present invention.

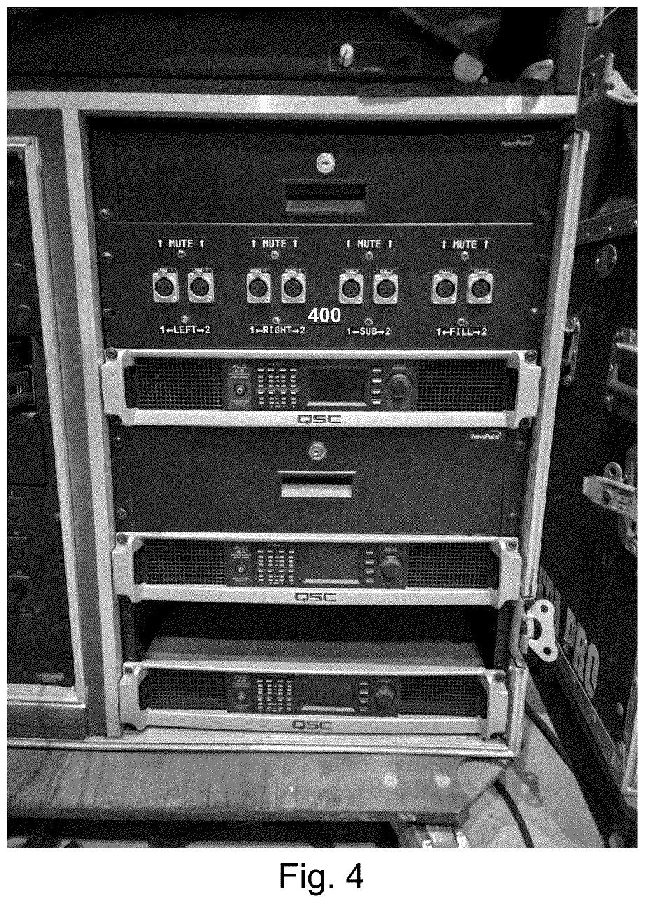

Second Example Method of Using a Simplified Mix Switcher. FIG. 4 shows the example embodiment of FIGS. 2 and 3 mounted 400 in a typical audio equipment rack, without cables plugged into it. The output cable is not visible, and it is behind the front panels and plugged into a mixing console (not shown), and the outputs of the mixing console are plugged into the amplifiers shown in the rack. In practice, an operator would:
a. switch all 4 mute switches to the muted position;
b. insert 8 cables into the front panel connectors: 4 from the first performance source, and 4 from the second performance source;
c. set all channel selectors to the same source 1 or 2, typically;
d. switch all 4 mute switches to the unmuted position;
e. wait for completion of the first performance;
f. switch all 4 mute switches to the muted position;
g. set all channel selectors to the other source, 2 or 1;
h. switch all 4 mute switches to the unmuted position;
i. wait for the completion of the second performance.

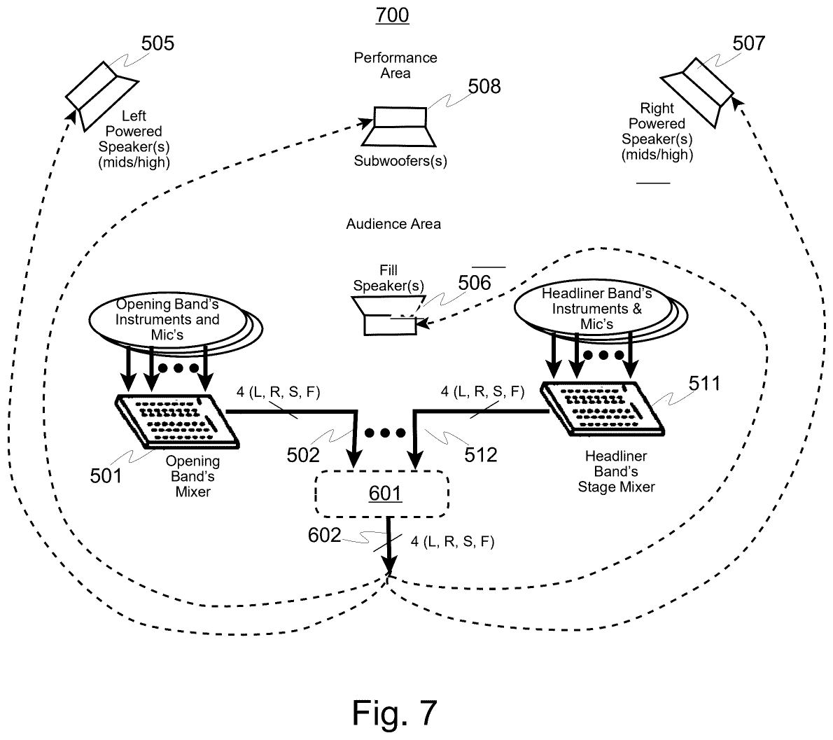

Third Example of Method of Using the Simplified Mix Switcher. Referring now to FIG. 7, a simplified mix switcher 601 is shown 700 receiving at its inputs two or sets of cables 502, 512 from two performer mixers 501, 511, without a separate “house” mixer, such that the outputs 602 of the mix switcher 601 go directly to powered (amplified) speakers 505, 506, 507 and 508. In this arrangement of components 700, the operator simply chooses A or B as the current output to the powered speakers by toggling the channel switches and the mute switches as previously discussed.

Fourth Example of Method of Using the Simplified Mix Switcher. In another example method of use of a simplified mix switcher according to the present invention, any of the forgoing configurations of equipment can be used to temporarily accommodate a “guest” mixer. For example, consider that one mixer, say the opening band's mixer in the foregoing arrangements, is actually a “guest” mixer belonging to a band who will only make one performance in the space. After the guest performer is finished, and while the mix switcher is switched to the other inputs (e.g., to the headliner band's mixer), the cables from the guest mixer can be safely and quietly unplugged from the inputs to the mix switcher. Then, a second “guest” performer's mixer can be plugged into the available inputs of the mix switcher, and when appropriate, the second guest mixer can be selected for driving the amplifiers or powered speakers. In this way, one set of inputs can be safely and quietly re-cabled while the other set of inputs are swapped.

Conclusion. The terminology used herein is for the purpose of describing particular one or more exemplary embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof, unless specifically stated otherwise.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed.

Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

The foregoing example embodiments do not define the extent or scope of the present invention, but instead are provided as illustrations of how to make and use at least one embodiment of the invention.

I/We claim:

1. A mix switcher with a simplified user interface comprising:
a first audio channel input connector configured to receive a first audio signal cable;
a second audio channel input connector configured to receive a second audio signal cable;
an audio channel output connector configured to receive an output signal cable; and
a portion of a user control panel having user-operable switches consisting of:
a channel selection switch to connect two or more conductors of one and only one of the channel input connectors to the audio channel output connector; and
a mute switch to short two or more conductors of the audio channel output connector to each other;
wherein an audio signal received at the user-selected channel input connector is conducted to the audio channel output connector with nominally unity-gain across an audio frequency spectrum.

2. The mix switcher of claim 1 wherein the channel selection switch comprises a metallic-contact toggle switch.

3. The mix switcher of claim 2 wherein the channel selection toggle switch comprises a double-pole double-throw switch.

4. The mix switcher of claim 1 wherein the mute switch comprises a metallic-contact toggle switch.

5. The mix switcher of claim 4 wherein the mute toggle switch comprises a single-pole double-throw switch.

6. The mix switcher of claim 1 wherein at least one audio channel input connector comprises an XLR connector.

7. The mix switcher of claim 1 wherein the audio channel output connector comprises an XLR connector.

8. The mix switcher of claim 1 wherein the portion of the user control panel comprises a rack-mountable panel.

9. The mix switcher of claim 1 wherein the portion of the user control panel comprises a portion of a desk-top enclosure.

10. The mix switcher of claim 1 wherein the channel selection switch comprises an electronic toggle switch.

11. The mix switcher of claim 1 wherein the mute switch comprises an electronic toggle switch.

12. A method of using a mix switcher comprising the steps of:
activating two or more channel mute switches of the mix switcher which shorts two or more conductors of two or more audio channel output connectors to each other;
connecting a first audio signal input cable to a first audio input connector of the mix switcher;
connecting a second audio input cable to a second channel input connector of the mix switcher;
connecting an audio signal output cable to an audio channel output connector of the mix switcher; and
thereafter, operating a channel selector switch which connects two or more conductors of one and only one of the two or more channel input connectors to the audio channel output connector;
deactivating at least the channel mute switch associates with the selected channel input; and
selectively activating or re-activating one or more of the two or more channel mute switches prior to disconnecting a corresponding audio input cable;
wherein an audio signal received at the user-selected channel input connector is conducted to the audio channel output connector with nominally unity-gain across an audio frequency spectrum.

13. The method as set forth in claim 12 wherein the audio output cable connects to one or more powered speakers.

14. The method as set forth in claim 13 wherein one or more of the audio signal input cables connects to one or more mixer panels.

15. The method as set forth in claim 12 wherein the audio output cable connects to a house mixer panel.

16. The method as set forth in claim 12 wherein the audio output cable connects to one or more audio amplifiers.

17. A method of manufacture of a mix switcher with a simplified user interface comprising:
disposing on a mix switcher a first audio channel input connector configured to receive a first audio signal cable;
disposing on a mix switcher a second audio channel input connector configured to receive a second audio signal cable;
disposing on a mix switcher an audio channel output connector configured to receive an output signal cable; and
providing a portion of a user control panel having user-operable switches consisting of:
a channel selection switch wired connect two or more conductors of one and only one of the channel input connectors to the audio channel output connector; and
a mute switch wired to short two or more conductors of the audio channel output connector to each other;
wherein an audio signal received at the user-selected channel input connector is conducted to the audio channel output connector with nominally unity-gain across an audio frequency spectrum.

18. The method as set forth in claim 17 wherein the disposing of the first, second, or both first and second input connectors comprises disposing an XLR connector.

19. The method as set forth in claim 17 wherein the disposing of the output connector comprises disposing an XLR connector.
